(19) United States
(12) Patent Application Publication
(10) Pub. No.: US 2023/0098311 A1
(43) Pub. Date: Mar. 30, 2023

(54) HEAT DISSIPATION APPARATUS WITH FLOW FIELD LOOP

(71) Applicant: AIC INC., Taoyuan City (TW)

(72) Inventors: Yen-Chih CHEN, Taoyuan City (TW); Hsih-Ting YOU, Taoyuan City (TW); Chi-Fu CHEN, Taoyuan City (TW)

(21) Appl. No.: 17/486,672

(22) Filed: Sep. 27, 2021

(51) Int. Cl. F28D 15/04

(52) U.S. Cl. CPC F28D 15/043

(57) ABSTRACT

A heat dissipation apparatus includes a vapor chamber and multiple flow field fins. The vapor chamber includes a lower plate part and an upper plate part. The lower plate part includes multiple flow channels, a first and a second confluence areas formed on the flow channels. The upper plate part covers on the lower plate part to enclose the flow channels, the first and second confluence areas. Each flow field fin includes an inlet channel, an outlet channel, and a circuitous channel. The inlet channel communicates with the first confluence area, the outlet channel communicates with the second confluence area, and the circuitous channel communicates between the inlet channel and the outlet channel in a single flow direction. The flow field fins are collectively as an inlet surface at one side adjacent to the outlet channel and as an outlet surface at another side adjacent to the inlet channel.

### BACKGROUND

### Technical Field

The present disclosure is related to a heat dissipation apparatus, in particular to a heat dissipation apparatus with a flow field loop.

### Description of Related Art

The related-art heat dissipation apparatus mainly uses a heat conducting plate attached to a heat source, and a plurality of fins are arranged on the heat conducting plate to form a heat sink. The heat conducting plate transfers the heat energy to the fins or heat sink to provide heat dissipation requirements.

As a demand for heat dissipation continues to increase, in addition to provide heat dissipation through adding fans or water cooling, the heat dissipation or cooling effects of the related-art heat dissipation apparatus may also be enhanced through a heat pipe or a vapor chamber with materials such as refrigerant or working fluid. However, the heat energy may still concentrate on the heat source during heat transferring, heating and heat dissipation of the heat dissipation apparatus may result in uneven, so that the heat dissipation or cooling effect may not be fully exerted.

Therefore, the inventor of the present disclosure focused on the above-mentioned related art, and proposed the present disclosure with reasonable design and made great efforts to solve the above-mentioned problems.

### SUMMARY

A main purpose of the present disclosure is to provide a flow field loop type heat dissipation apparatus, which provides refrigerant or working fluid through a circuitous channel to form a uniform flow field, so that the heat dissipation apparatus may achieve the purpose of heat dissipation and cooling in a natural circulation state.

In order to achieve the above-mentioned purpose, the present disclosure provides a flow field loop type heat dissipation apparatus includes a vapor chamber and a plurality of flow field fins are arranged on the vapor chamber. The vapor chamber includes a lower plate part and an upper plate part, the lower plate part includes a plurality of flow channels, a first confluence area and a second confluence area are respectively disposed on a front end and a rear end of the flow channels, and the upper plate part covers on the lower plate part to enclose the flow channels, the first confluence area, and the second confluence area. Each of the flow field fins includes an inlet channel, an outlet channel, and a circuitous channel disposed therein. The inlet channel communicates with the first confluence area, the outlet channel communicates with the second confluence area, the circuitous channel communicates between the inlet channel and the outlet channel in a single flow direction. The flow field fins are collectively configured to serve as an inlet surface at one side adjacent to the outlet channel and serve as an outlet surface at another side adjacent to the inlet channel.

### BRIEF DESCRIPTION OF DRAWINGS

FIG. 1 is a perspective assembled view of the present disclosure.

FIG. 2 is a perspective exploded view of the present disclosure.

FIG. 3 is an enlarged view based on A of FIG. 2.

FIG. 4 is a cross-sectional view of the present disclosure from one view angle.

FIG. 5 is a cross-sectional view of the present disclosure from another view angle.

### DETAILED DESCRIPTION

The technical content and detailed description of the present disclosure are now described with the drawings as follows. The present disclosure is not limited thereto.

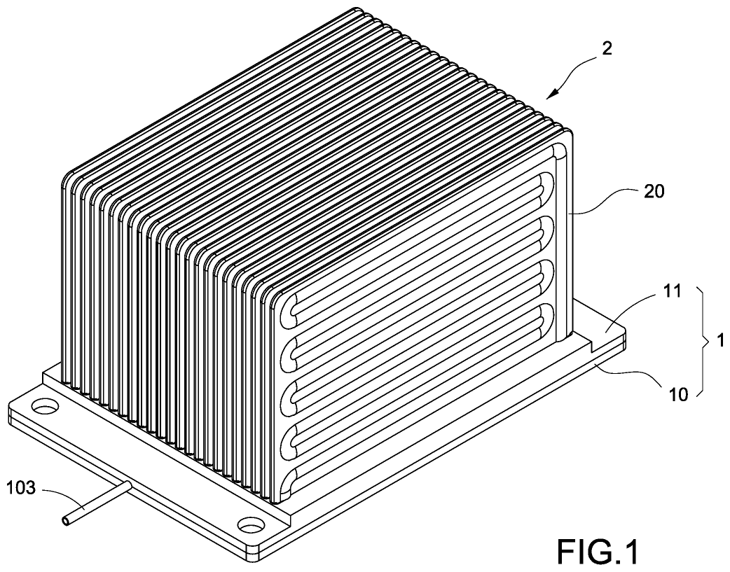

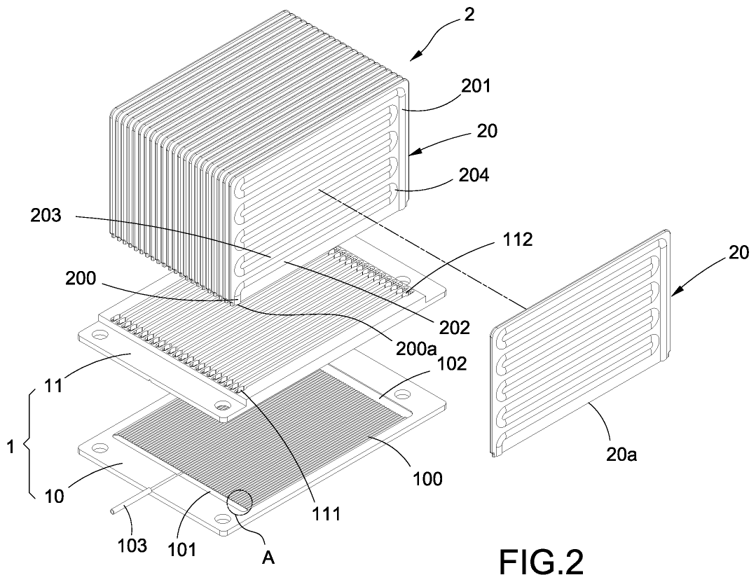

Please refer to FIG. 1 and FIG. 2, FIG. 1 is a perspective assembled view of the present disclosure, and FIG. 2 is a perspective exploded view of the present disclosure. The present disclosure provides a heat dissipation apparatus with a flow field loop (flow field loop type heat dissipation apparatus), the heat dissipation apparatus includes a vapor chamber 1 and a plurality of flow field fins 2 arranged on the vapor chamber 1.

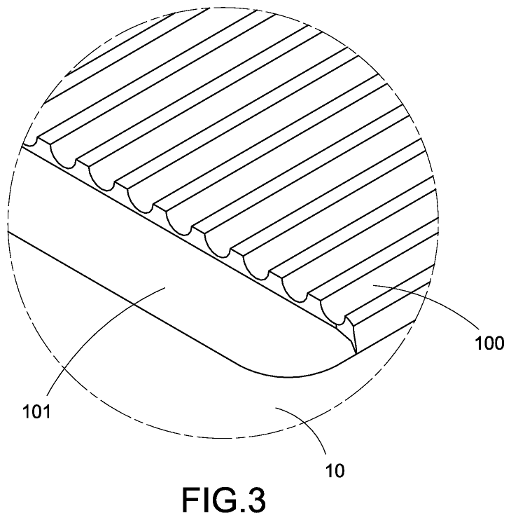

The vapor chamber 1 includes a lower plate part 10 and an upper plate part 11. The lower plate part 10 includes a plurality of flow channels 100 (as shown in FIG. 3) for refrigerant or working fluid (not shown in figures) to flow through. A first confluence area 101 and a second confluence area 102 are respectively formed on a front end and a rear end of the flow channels 100. An injection channel 103 is arranged on the lower plate part 10, and the injection channel 103 communicates with the first confluence area 101 or the second confluence area 102 for injection of refrigerant or working fluid. The upper plate part 11 covers on the lower plate part 10 to enclose the flow channels 100, the first confluence area 101, and the second confluence area 102. A plurality of embedding grooves 110 are arranged on the upper plate part 11 for the plurality of flow field fins 2 to be embedded. A front end of each embedding groove 110 includes a first through hole 111 corresponding to the first confluence area 101, and a rear end of each embedding groove 110 includes a second through hole 112 corresponding to the second confluence area 102.

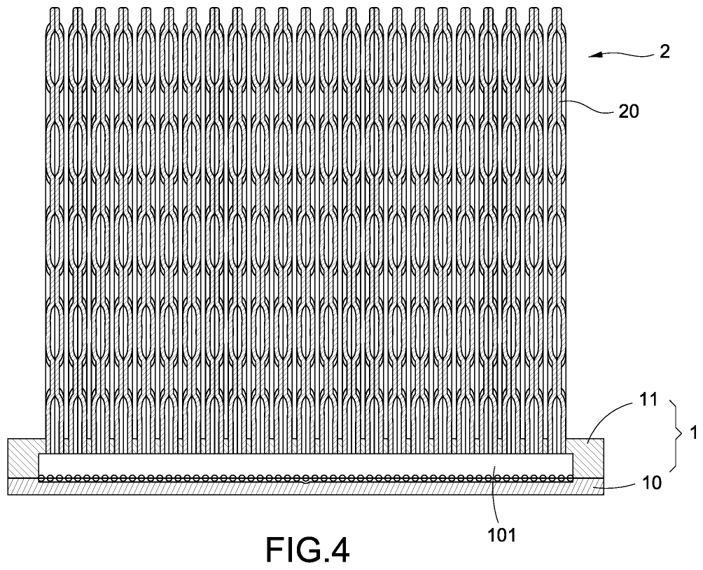

The flow field fins 2 are erected on the vapor chamber 1 and arranged spacedly (as shown in FIG. 4), and each of the flow field fins 2 is formed by two half-plates 20 in symmetry covering with each other. In an embodiment of the present disclosure, each half plate 20 is made of an inflatable plate. Each of the flow field fins 2 includes a lower edge 20a embedded in each embedding groove 110, and an inlet channel 200 and an outlet channel 201 are formed in each of the flow field fins 2. The inlet channel 200 is located on the front side of the flow field fin 2 and communicates with the lower edge 20a of the flow field fin 2 to form an intake 200a, and the outlet channel 201 is located on the rear side of the flow field fin 2 and communicates with the lower edge 20a of the flow field fin 2 to form an offtake 201a. The intake 200a of each flow field fin 2 is corresponding to the first through hole 111 of each embedding groove 110, and the offtake 201a of each flow field fin 2 is corresponding to the second through hole 112 of each embedding groove 110.

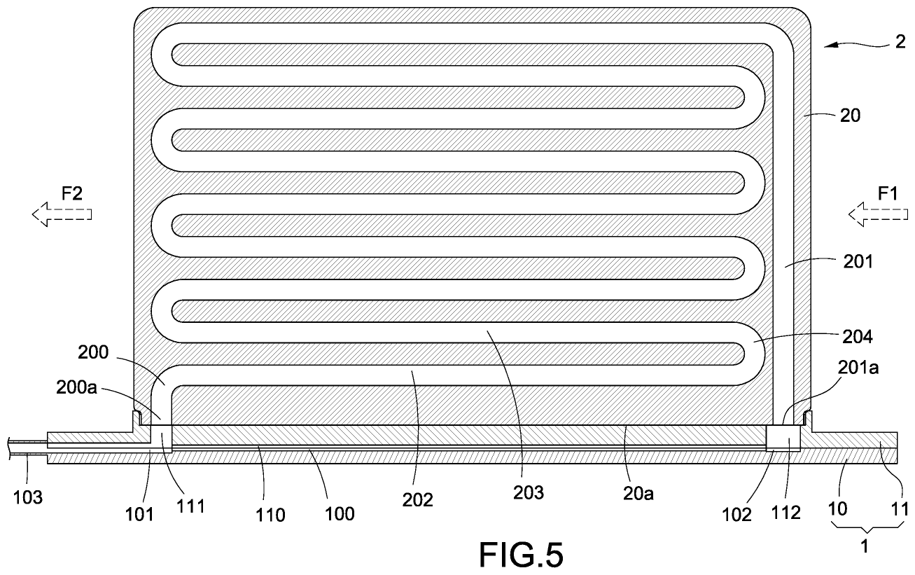

As shown in FIG. 5, each of the flow field fins 2 has a circuitous channel communicating between the inlet channel 200 and the outlet channel 201 in a single flow direction. The circuitous channel includes a plurality of first channels 202, a plurality of second channels 203, and a plurality of curved channels 204. The first channels 202 are extended horizontally from the inlet channel 200 toward the outlet channel 201 as one flow direction. The second channels 203 are extended horizontally from the outlet channel 201 toward the inlet channel 200 as another flow direction. The curved channels 204 communicate between the first channels 202 and the second channels 203 to connect the first channels 202 and the second channels 203 in series to form the single flow direction. Further, the first channel 202 and the second channel 203 are arranged alternately from bottom to top as from the side adjacent to the lower edge 20a of the flow field fin 2, and the second channel 203 located uppermost communicates with the outlet channel 201 extended vertically downward to form the circuitous channel.

Therefore, the flow field loop type heat dissipation apparatus of the present disclosure is obtained by the above-mentioned structure.

As shown in FIG. 5, when the present disclosure is used, the external airflow may flow from airflow F1 to airflow F2 by matching with an airflow direction of an external environment or adding another apparatus such as a fan (not shown in figures). That is, the airflow F1 shown in FIG. 5 is at an inlet surface, and the outlet channel 201 of each of the flow field fin 2 is directed to the inlet surface, so that the air flow F1 enters the flow field fins 2 from the side of the spacey outlet channel 201 to pass through the gaps between the flow field fins 2, and the air flow F1 is expelled from the other side of the flow field fin 2 as an outlet surface, that is, the direction of the airflow F2. Therefore, when the refrigerant or working fluid (not shown in figures) in the vapor chamber 1 is heated and vaporized, the location of the inlet channel 200 is lower than the location of the outlet channel 201, and thus the vaporized refrigerant or working fluid may enter each of the flow field fin 2 though the intake 200a. The refrigerant or working fluid is continuously to be vaporized and passes through the circuitous channel from bottom to top. When the vaporized refrigerant or working fluid is being pushed to the outlet channel 201, the outlet channel 201 is located toward the inlet surface and a better cooling effect may be achieved. Therefore, when the refrigerant or working fluid returned to a liquid state may quickly flow back into the vapor chamber 1 along the outlet channel 201 aligned in the vertical direction, so that the refrigerant or working fluid sealed in the vapor chamber 1 may form a natural circulation state.

In summary, the present disclosure may achieve an intended purpose and solve problems in related art.

While this disclosure has been described by means of specific embodiments, numerous modifications and variations could be made thereto by those skilled in the art without departing from the scope and spirit of this disclosure set forth in the claims.

What is claimed is:

1. A heat dissipation apparatus with a flow field loop, the heat dissipation apparatus comprising:
a vapor chamber, comprising a lower plate part and an upper plate part, wherein the lower plate part comprises a plurality of flow channels, a first confluence area and a second confluence area respectively disposed on a front end and a rear end of the flow channels, and the upper plate part covers on the lower plate part to enclose the flow channels, the first confluence area, and the second confluence area; and
a plurality of flow field fins, arranged on the vapor chamber, and each of the flow field fins comprising an inlet channel, an outlet channel, and a circuitous channel disposed therein, wherein the inlet channel communicates with the first confluence area, the outlet channel communicates with the second confluence area, the circuitous channel communicates between the inlet channel and the outlet channel in a single flow direction;
wherein the flow field fins are collectively configured to serve as an inlet surface at one side adjacent to the outlet channel and serve as an outlet surface at another side adjacent to the inlet channel.

2. The heat dissipation apparatus in claim 1, wherein, the lower plate part comprises an injection channel arranged thereon to communicate with the first confluence area or the second confluence area.

3. The heat dissipation apparatus in claim 1, wherein, the upper plate part comprises a plurality of embedding grooves arranged thereon, and the flow field fins are embedded in the embedding grooves.

4. The heat dissipation apparatus in claim 3, wherein, each embedding groove comprises a first through hole disposed on a front end thereof corresponding to the first confluence area and a second through hole disposed on a rear end thereof corresponding to the second confluence area.

5. The heat dissipation apparatus in claim 4, wherein, each of the flow field fins comprises a lower edge embedded in each embedding groove, the inlet channel of each of the flow field fins communicates with the lower edge to configure an intake, the outlet channel of each of the flow field fins communicates with the lower edge to configure an offtake, the intake of each of the flow field fins is corresponding to the first through hole, and the offtake of each of the flow field fins is corresponding to the second through hole.

6. The heat dissipation apparatus in claim 1, wherein, each of the flow field fins is configured by two half-plates in symmetry covering with each other.

7. The heat dissipation apparatus in claim 6, wherein, the half plate comprises an inflatable plate.

8. The heat dissipation apparatus in claim 1, wherein, the circuitous channel comprises a plurality of first channels, a plurality of second channels, and a plurality of curved channels, the first channels are extended horizontally from the inlet channel toward the outlet channel as one flow direction, the second channels are extended horizontally from the outlet channel toward the inlet channel as another flow direction, the curved channels communicate between the first channels and the second channels to connect the first channels and the second channels in series for the single flow direction.

9. The heat dissipation apparatus in claim 8, wherein, the circuitous channel is configured in a manner of arranging the first channels and the second channels alternately from bottom to top in each of the flow field fins, and communicating the second channel located uppermost with the outlet channel extended vertically downward.

10. The heat dissipation apparatus in claim 9, wherein, a location of the inlet channel is lower than a location of the outlet channel.
